(19) United States
(12) Patent Application Publication
(10) Pub. No.: US 2018/0019234 A1
(43) Pub. Date: Jan. 18, 2018

(54) DISPLAY DEVICES AND METHODS FOR FORMING THE SAME

(71) Applicant: InnoLux Corporation, Miao-Li County (TW)

(72) Inventor: Shun-Yuan HU, Miao-Li County (TW)

(21) Appl. No.: 15/644,047

(22) Filed: Jul. 7, 2017

Related U.S. Application Data
(60) Provisional application No. 62/361,543, filed on Jul. 13, 2016.

(30) Foreign Application Priority Data
Jan. 26, 2017 (CN) 201710061424.2

(51) Int. Cl. H01L 25/16; H01L 33/62; H01L 23/00; H01L 25/075; H01L 27/12

(52) U.S. Cl. CPC H01L 25/167; H01L 24/09; H01L 24/17; H01L 24/32; H01L 24/73; H01L 24/03; H01L 24/83; H01L 24/92; H01L 25/0753; H01L 33/62; H01L 24/81; H01L 27/1244; H01L 2224/16148; H01L 2224/1703; H01L 2224/32148; H01L 2224/73204; H01L 2224/9211; H01L 2924/12041; H01L 2933/0066; H01L 2924/13069

(57) ABSTRACT

A display device is provided. The display device includes a first conductive pad disposed on a substrate, wherein the first conductive pad has a contact area that is adjacent to the substrate. The display device also includes a first bonding material disposed on the first conductive pad, wherein the first bonding material has a sectional area that is parallel to a surface of the substrate. The display device further includes a second conductive pad disposed on the first bonding material, and a first illumination structure disposed on the second conductive pad, wherein the sectional area of the first bonding material is smaller than the contact area of the first conductive pad.

### CROSS REFERENCE TO RELATED APPLICATIONS

This application claims priority of China Patent Application No. 201710061424.2, filed on Jan. 26, 2017, which claims the benefit of priority from a provisional application of, U.S. Patent Application No. 62/361,543 filed on Jul. 13, 2016, the entirety of which is incorporated by reference herein.

### BACKGROUND OF THE INVENTION

### Field of the Invention

The invention relates to display devices, and in particular to display devices formed by using a eutectic bonding method to bond the illustration structures to the substrate, and methods for forming the same.

### Description of the Related Art

Among the bonding methods used in the fabrication of display devices, eutectic bonding is generally relatively stable. The eutectic bonding method utilizes eutectic alloy materials with low melting temperature. The materials can transform directly from solid to liquid during their melting process without passing through an equilibrium point between the solid and liquid states. The eutectic temperature of this kind of material (that is, the melting temperature of the material) can be lower than each of the melting points of their component metals.

Although existing display devices packaged by using a eutectic bonding method and methods for forming the same have been adequate for their intended purposes, they have not been entirely satisfactory in all respects. Therefore, there are still some problems that remain to be overcome in regards to the eutectic bonding technology used in manufacturing display devices.

### BRIEF SUMMARY OF THE INVENTION

Some embodiments of the disclosure provide display devices and methods for forming the same. Generally, in the eutectic bonding process which makes several illumination structures bond to the substrate, the thicknesses of the illumination structures are different, or the thicknesses of the conductive pads on each of the illumination structures are different. Therefore, the conductive pads on the thinner illumination structures or the thinner conductive pads on the illumination structure may not form a eutectic bond to the corresponding conductive pad on the substrate. Forcing them to be eutectic bonded may cause damage to the illumination structures, or short circuits between the conductive pads.

During the process of eutectic bonding, the thicker illumination structures or the thicker conductive pads will force more bonding materials outwardly extruded than the thinner illumination structures or the thinner conductive pads. To solve this problem, some embodiments of the disclosure include providing accommodation spaces between the conductive pads on the substrate and the conductive pads on the illumination structures by minimizing sectional areas of the bonding materials or patterning the bonding materials, such that the extra bonding materials produced by extrusion enter into the accommodation spaces, and short circuits between the conductive pads can be avoided.

Furthermore, in order to ensure a uniform distance between the substrate and each of the surfaces of the illumination structures which is far from the substrate when the bonding process is done, some embodiments of the disclosure include disposing several of the same height spacers between the substrate and the illumination structures. Moreover, by disposing spacers between two adjacent conductive pads on the substrate or on the illumination structures, the problems of short circuits between two adjacent conductive pads on the substrate or on the illumination structures can be avoided after performing the bonding process.

Some embodiments of the disclosure provide a display device. The display device includes a first conductive pad disposed on a substrate, wherein the first conductive pad has a contact area that is adjacent to the substrate. The display device also includes a first bonding material disposed on the first conductive pad, wherein the first bonding material has a sectional area that is parallel to a surface of the substrate. The display device further includes a second conductive pad disposed on the first bonding material, and a first illumination structure disposed on the second conductive pad, wherein the sectional area of the first bonding material is smaller than the contact area of the first conductive pad.

Some embodiments of the disclosure provide a display device. The display device includes a first conductive pad disposed on a substrate, a first bonding material disposed on the first conductive pad, and a second conductive pad disposed on the first bonding material. In addition, the display device further includes a first illumination structure disposed on the second conductive pad, and a first spacer disposed between the substrate and the first illumination structure.

Some embodiments of the disclosure provide a method for forming a display device. The method includes forming a first conductive pad on a substrate, wherein the first conductive pad has a contact area that is adjacent to the substrate. The method also includes forming a second conductive pad on a first illumination structure, and forming a first bonding material on the first conductive pad, wherein the first bonding material has a sectional area that is parallel to a surface of the substrate, the sectional area of the first bonding material is smaller than the contact area of the first conductive pad, and performing a bonding process to bond the first illumination structure to the substrate.

Some embodiments of the disclosure provide a method for forming a display device. The method includes forming a first conductive pad on a substrate, and forming a second conductive pad on an illumination structure. The method also includes forming a spacer on the substrate or the illumination structure, and forming a glue coating on the substrate and the first conductive pad. The method further includes forming a bonding material on the glue coating, and the bonding material is embedded in the glue coating, wherein the bonding material has a thickness that is greater than the thickness of the spacer, and performing a bonding process to bond the illumination structure to the substrate.

Some embodiments of the disclosure provide a method for forming a display device. The method includes forming a first conductive pad on a substrate, and forming a second conductive pad on an illumination structure. The method further includes forming a glue coating on the substrate and the first conductive pad, or forming the glue coating on the illumination structure and the second conductive pad, wherein the glue coating has a spacer therein. In addition, the method includes forming a bonding material on the glue coating, and the bonding material is embedded in the glue coating, wherein the bonding material has a thickness that is greater than the thickness of the spacer, and performing a bonding process to bond the illumination structure to the substrate.

A detailed description is given in the following embodiments with reference to the accompanying drawings.

### BRIEF DESCRIPTION OF THE DRAWINGS

The disclosure can be more fully understood from the following detailed description when read with the accompanying figures. It is worth noting that in accordance with standard practice in the industry, various features are not drawn to scale. In fact, the dimensions of the various features may be arbitrarily increased or reduced for clarity of discussion.

FIGS. 1 and 2 are cross-sectional views of display devices.

FIGS. 3A, 3B and 3C are cross-sectional views illustrating an exemplary sequential formation process of a display device in accordance with some embodiments.

FIG. 4 is a cross-sectional view of a display device in accordance with some embodiments.

FIGS. 5A and 5B are cross-sectional views illustrating an exemplary sequential formation process of a display device in accordance with some embodiments.

FIGS. 6A to 6F are top views of display devices illustrating the bonding materials on the conductive pads along line A-A of FIG. 5A, line B-B of FIG. 5A, line A′-A′ of FIG. 5B or line B′-B′ of FIG. 5B.

FIGS. 7A to 7D are cross-sectional views illustrating an exemplary sequential formation process of a display device in accordance with some embodiments.

FIGS. 8A and 8B are cross-sectional views illustrating an exemplary sequential formation process of a display device in accordance with some embodiments.

FIGS. 9A to 9D are cross-sectional views illustrating an exemplary sequential formation process of a display device in accordance with some embodiments.

FIGS. 10A and 10B are cross-sectional views illustrating an exemplary sequential formation process of a display device in accordance with some embodiments.

FIGS. 11A to 11E are cross-sectional views illustrating an exemplary sequential formation process of a display device in accordance with some embodiments.

FIGS. 12A to 12E are cross-sectional views illustrating an exemplary sequential formation process of a display device in accordance with some embodiments.

FIGS. 13A to 13E are cross-sectional views illustrating an exemplary sequential formation process of a display device in accordance with some embodiments.

### DETAILED DESCRIPTION OF THE INVENTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various embodiments. This repetition is for simplicity and clarity and does not in itself dictate a relationship between the various embodiments and/or configurations discussed.

Some embodiments are described below. Throughout the various views and illustrative embodiments, like reference numbers are used to designate like features. It should be understood that additional operations can be provided before, during, and after the method, and some of the operations described can be replaced or eliminated for other embodiments of the method.

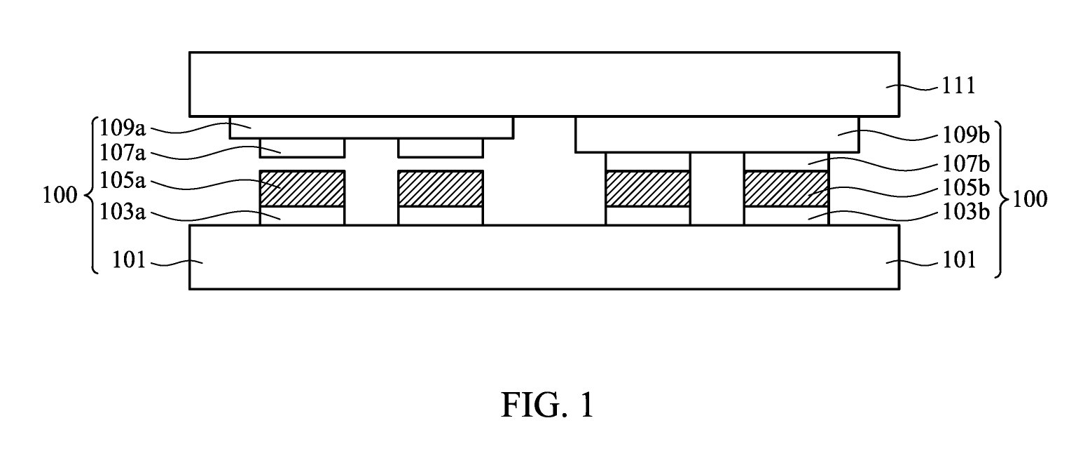

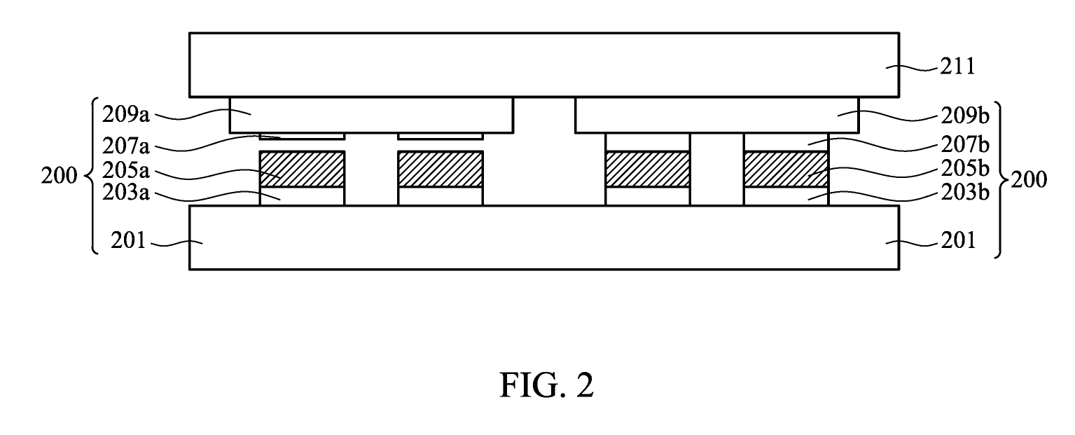

FIGS. 1 and 2 are cross-sectional views of display devices 100 and 200. In particular, FIGS. 1 and 2 are used to illustrate the eutectic bonding problems caused when the conductive pads on the thinner illumination structure or the thinner conductive pads on the illumination structure are bonded to the corresponding conductive pads in the display devices 100 and 200.

As shown in FIG. 1, a substrate 101 of a display device 100 has several first conductive pads 103a and several third conductive pads 103b thereon. Each of the first conductive pads 103a has a respective first bonding material 105a thereon, and each of the second conductive pads 103b has a respective second bonding material 105b thereon. In addition, the display device 100 has a first illumination structure 109a and a second illumination structure 109b with different heights. Specifically, the first illumination structure 109a is thinner than the second illumination structure 109b.

Several second conductive pads 107a are formed on the bottom surface of the first illumination structure 109a. The first illumination structure 109a and the second conductive pads 107a located on its bottom surface compose a first illumination component. Several fourth conductive pads 107b are formed on the bottom surface of the second illumination structure 109b. The second illumination structure 109b and the fourth conductive pads 107b located on its bottom surface compose a second illumination component. The first illumination structure 109a and the second illumination structure 109b are bonded to the substrate 101 by utilizing a bonding head 111. In particular, the locations of the first bonding materials 105a are corresponding to the locations of the second conductive pads 107a in the direction perpendicular to the surface of the substrate 101, and the locations of the second bonding materials 105b are corresponding to the locations of the fourth conductive pads 107b in the direction perpendicular to the surface of the substrate 101.

As shown in FIG. 1, since there is a difference in thickness between the first illumination structure 109a and the second illumination structure 109b, when the substrate 101 is bonded to the second illumination structure 109b, there may still have gaps between the first illumination structure 109a and the substrate 101, such that the first illumination structure 109a and the substrate 101 may not be fully bonded with each other. At this time, if a pressure is applied forcibly to the bonding head 111, the first illumination structure 109a and the second illumination structure 109b may be damaged, or the second bonding materials 105b may be outwardly extruded because of the excessive pressure applied, each two of the adjacent second bonding materials 105b may be in contact with each other and the problems of short circuits may be caused.

As shown in FIG. 2, some components of the display device 200 shown in FIG. 2 are similar to those of the display device 100 shown in FIG. 1 and are not repeated herein for simplicity. It is worth noting that a first illumination structure 209a and a second illumination structure 209b of the display device 200 shown in FIG. 2 have the same thickness. However, since the second conductive pads 207a and the fourth conductive pads 207b of the display device 200 are different in thickness, the problems which are similar to that of the display device 100 may be caused during the bonding process of the display device 200. Specifically, since the second conductive pads 207a of the display device 200 have a thickness that is less than the thickness of the fourth conductive pads 207b, when the second illumination structure 209b is bonded to the substrate 201, there may still have gaps between the first illumination structure 209a and the substrate 201, such that the first illumination structure 209a and the substrate 201 may not be fully bonded with each other. At this time, if a pressure is applied forcibly to the bonding head 211, the aforementioned problems may be caused.

To sum up, when the thickness of the first illumination components is not consistent with the thickness of the second illumination components, the bonding process between the substrate and the first and second illumination components will not be completed successfully, and the aforementioned problems may be easily caused.

One of the purposes of the embodiments below is to solve the aforementioned problems. The embodiments below use display devices including the first illumination structure 109a and the second illumination structure 109b with different thicknesses as examples to illustrate how to solve the foregoing problems, however, the embodiments of the present disclosure are not limited to these examples. The display devices may also include the first conductive pads 103a and the third conductive pads 103b with different thicknesses, or the second conductive pads 107a and the fourth conductive pads with different thicknesses.

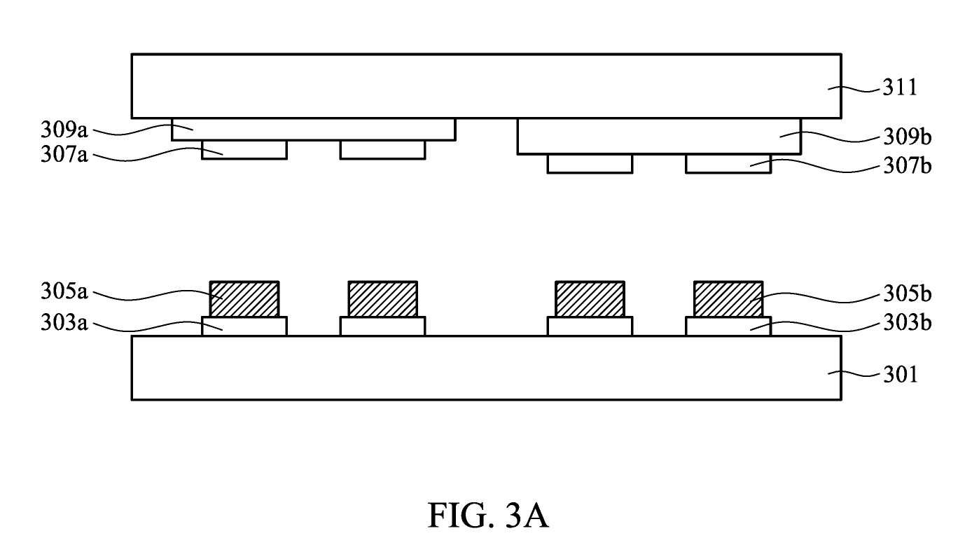

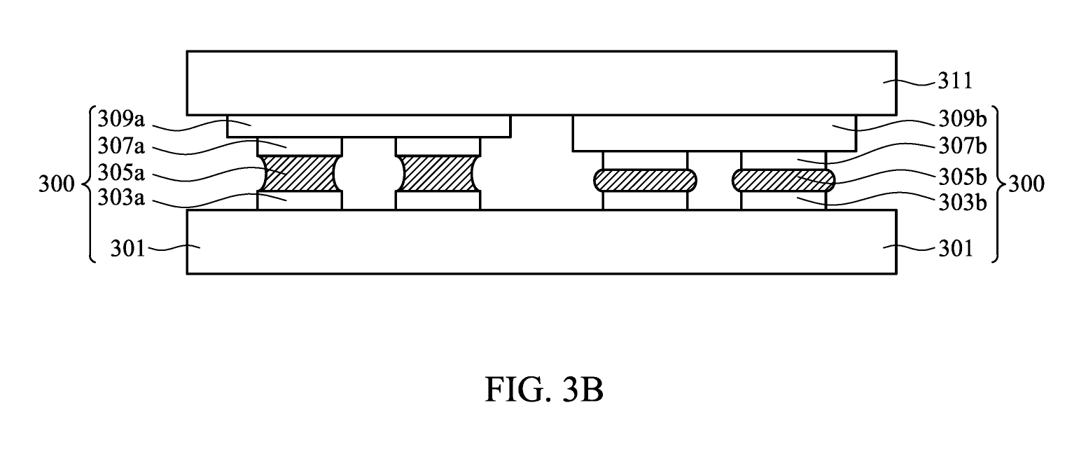

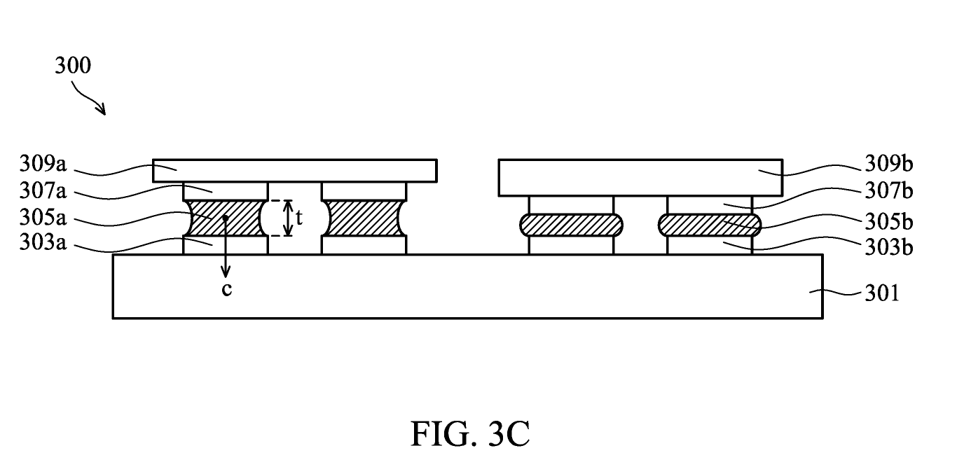

FIGS. 3A, 3B and 3C are cross-sectional views illustrating an exemplary sequential formation process of a display device 300 in accordance with some embodiments.

As shown in FIG. 3A, several first conductive pads 303a and several third conductive pads 303b are formed on a substrate 301, in accordance with some embodiments. In some embodiments, the substrate 301 may be array substrates having thin film transistors (TFT) formed therein. The first conductive pads 303a and the third conductive pads 303b may be formed by using deposition process, for example, chemical vapor deposition (CVD), physical vapor deposition (PVD), atomic layer deposition (ALD), metal organic chemical vapor deposition (MOCVD), spin coating, or sputtering to form a conductive layer. Then, the conductive layer is patterned to form several conductive pads be patterning process, the patterning process includes photolithography and etching processes.

As shown in FIG. 3A, a respective one of first bonding materials 305a is formed on each of the first conductive pads 303a, and a respective one of second bonding materials 305b is formed on each of the third conductive pads 303b. It is worth noting that the first bonding materials 305a and the second bonding materials 305b have sectional areas that are parallel to the surface of the substrate 101. The first conductive pads 303a and the third conductive pads 303b have contact areas that are adjacent to the substrate 101, and the sectional areas of the first bonding materials 305a are smaller than the contact areas that are adjacent to the substrate 301, and the sectional areas of the second bonding materials 305b are smaller than the contact areas that are adjacent to the substrate 301. In some embodiments, the first and second bonding materials 305a and 305b may be formed by using injecting or stamping methods. The first and second bonding materials 305a and 305b may be made of metals or alloys with low melting points. In some embodiments, the materials of the first and second bonding materials 305a and 305b may be eutectic materials with melting points less than 350° C., for example, metal alloys like tin (Sn), gallium (Ga), indium (In), gold (Au), zinc (Zn), bismuth (Bi), silver (Ag), an alloy thereof or another applicable material. In other embodiments, the materials of the first and second bonding materials 305a and 305b may be conductive thermoset materials which can be heated. In addition, the materials of the first conductive pads 303a and the third conductive pads 303b are similar to, or the same as, those used to form the first and second bonding materials 305a and 305b and are not repeated herein for simplicity.

On the other hand, as shown in FIG. 3A, the first illumination structure 309a and the second illumination structure 309b are adsorbed or adhered by the bonding head 311 of the thermal-compression bonding equipment. In some embodiments, the first illumination structure 309a is thinner than the second illumination structure 309b. Several second conductive pads 307a are formed on the bottom surface of the first illumination structure 309a, the first illumination structure 309a and the second conductive pads 307a located on its bottom surface compose a first illumination component, and several fourth conductive pads 307b are formed on the bottom surface of the second illumination structure 309b, the second illumination structure 309b and the fourth conductive pads 307b located on its bottom surface compose a second illumination component. In some embodiments, the first and second illumination structures 309a and 309b may be light-emitting diodes (LED). In addition, the processes and materials of the second and fourth conductive pads 307a and 307b are similar to, or the same as, those used to form the first and third conductive pads 303a and 303b and are not repeated herein for simplicity.

As shown in FIG. 3B, a bonding process is performed by using the bonding head 311 to make the first and second illumination structures 309a and 309b bond to the substrate 301 at the same time, such that the display device 300 is formed under the bonding head 311, in accordance with some embodiments. The purpose of the bonding process is to help the bonding between the substrate 101 and the first and second illumination structures 309a, 309b by applying temperature and pressure through the bonding head 311. Generally, the temperature applied through the bonding head 311 depends on the materials of the first, second, third and fourth conductive pads 105a, 107a, 105b, 107b and the materials of the first and second boding materials 105a, 105b. In some embodiments, the temperature applied through the bonding head 311 is less than 350° C., for example, in a range from about 100° C. to about 300° C. Moreover, the pressure applied through the bonding head 311 depends on the quantities of the illumination structures 309a and 309b which are intended to be bonded.

Next, as shown in FIG. 3A, since the sectional areas of the first and second bonding materials 305a, 305b are smaller than the contact areas of the first and third conductive pads 303a, 303b that are adjacent to the substrate 101 before bonding, there are accommodation spaces between the first and second conductive pads 303a, 307a, and between the third and fourth conductive pads 303b, 307b. After bonding, as shown in FIG. 3B, a portion of the second bonding materials 305b under the thicker second illumination structure 309b is extruded due to the pressure applied in the bonding process, the extruded portion may not be in contact with other conductive components nearby so that the problems of short circuits may be avoided. At the same time, after performing the bonding process, the first and second illumination structures 309a, 309b may be successfully bonded to the substrate 101. Moreover, since the first illumination structure 309a is thicker than the second illumination structure 309b, after bonding, as shown in FIG. 3B, the first bonding materials 305a under the first illumination structure 309a have concave cross-sectional contours, and the second bonding materials 305b under the second illumination structure 309b have convex cross-sectional contours.

Next, as shown in FIG. 3C, the bonding head 311 is removed after performing the bonding process. In some embodiments, a protection layer (not shown) is disposed covering the display device 300. Moreover, another substrate (not shown) is disposed on the first illumination structure 309a and the second illumination structure 309b to entirely cover the display device 300. As shown in FIG. 3C on the left, after performing the bonding process and removing the bonding head 311, the sectional areas of the first bonding materials 305a of the display device 300 are smaller than the contact areas of the first conductive pads 303a that are adjacent to the substrate 101. Specifically, the first bonding materials 305a have a center “c” and a thickness “t”, and the first bonding materials 305a has sectional areas that are parallel to the surface of the substrate 101, the sectional areas are located in a range from the center “c” of the first bonding materials 305a plus 15% of the thickness “t” of the first bonding materials 305a upward or downward.

In other words, the first bonding materials 305a have cross-sections perpendicular to the substrate 301. In the cross-sections, the first bonding materials 305a have concave cross-sectional contours in the range from the center “c” of the first bonding materials 305a plus 15% of the thickness “t” upward or downward.

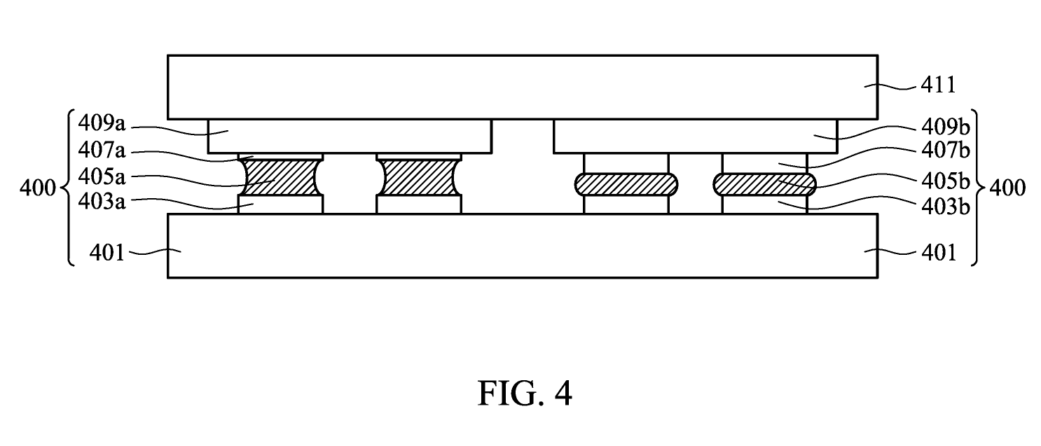

FIG. 4 is a cross-sectional view of a display device 400 in accordance with some embodiments.

As shown in FIG. 4, the display device 400 has components which are similar to those of the display device 300 shown in FIG. 3B and are not repeated herein for simplicity, in accordance with some embodiments. It is worth noting that the display device 400 shown in FIG. 4 has a first illumination structure 409a and a second illumination structure 409b which have the same thickness, and the display device 400 has second conductive pads 407a and fourth conductive pads 407b which have different thicknesses. Specifically, the second conductive pads 407a are thinner than the fourth conductive pads 407b. In addition, after performing the bonding process, the bonding head 411 is removed to form the display device 400.

Similar to the process of the display device 300, the display device 400 has a limitation that the sectional areas of the first and second bonding materials 405a, 405b are smaller than the contact areas of the first and third conductive pads 403a, 403b that are adjacent to the substrate 401 before performing the bonding process. Therefore, the first and second illumination structures 409a, 409b can be bonded to the substrate 401 successfully. Moreover, since the second conductive pads 407a are thinner than the fourth conductive pads 407b, the first bonding materials 405a under the second conductive pads 407a have concave cross-sectional contours, and the second bonding materials 405b under the fourth conductive pads 407b have convex cross-sectional contours.

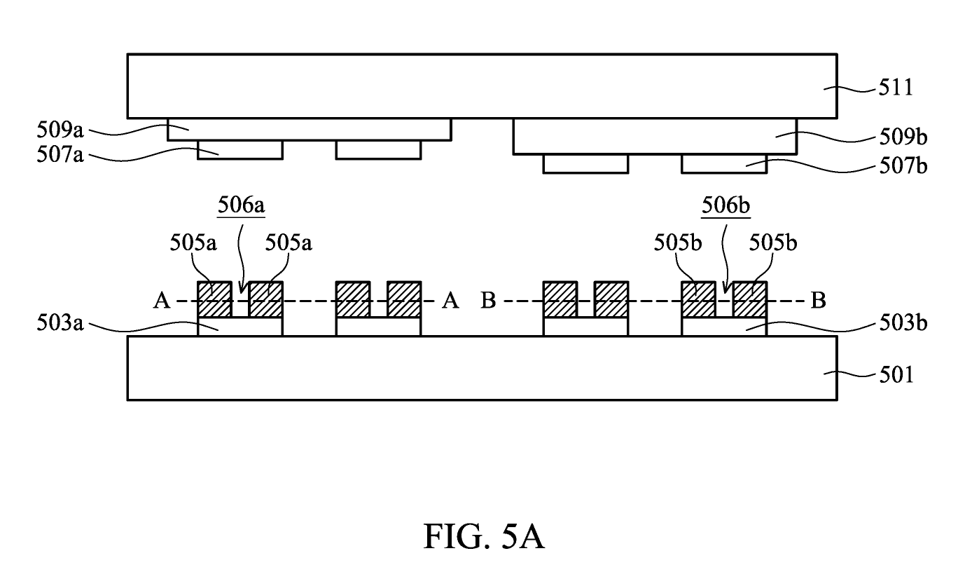

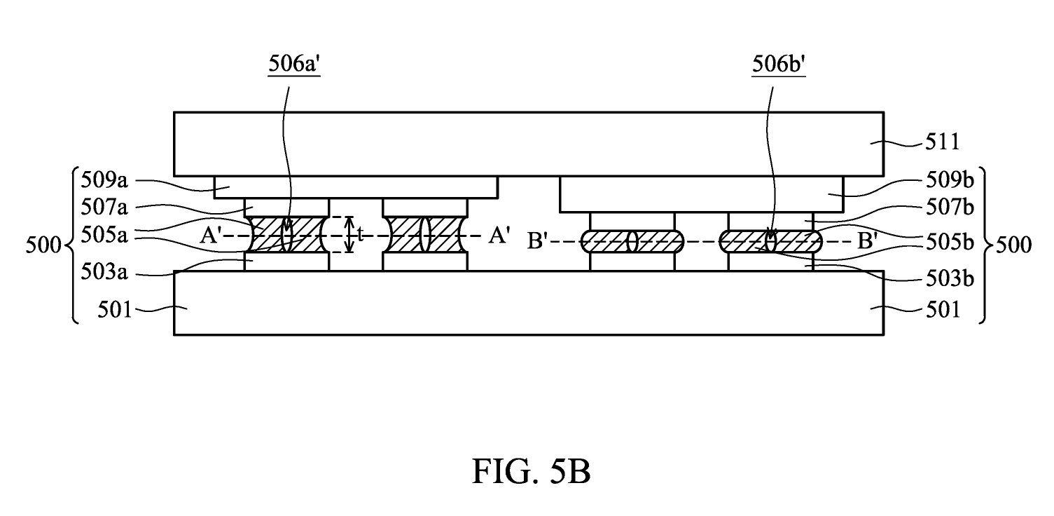

FIGS. 5A and 5B are cross-sectional views illustrating an exemplary sequential formation process of a display device 500 in accordance with some embodiments. The display device 500 has components which are similar to those of the display device 300 shown in FIG. 3B and are not repeated herein for simplicity.

As shown in FIG. 5A, patterned first and second bonding materials 505a, 505b are disposed respectively on the first and third conductive pads 503a, 503b, in accordance with some embodiments. It is worth noting that the patterned first and second bonding materials 505a, 505b have gaps or holes inside. In some embodiments, as shown in FIG. 5A, the patterned first bonding materials 505a have first gaps 506a inside, and the patterned second bonding materials 505b have second gaps 506b inside.

Next, as shown in FIG. 5B, a bonding process is performed. The first and second illumination structures 509a, 509b are bonded to the substrate 501 at the same time through a bonding head 511 to form the display device 500 under the bonding head 511. In particular, the first gaps 506a and the second gaps 506b are squeezed and minimized into first holes 506a′ and second holes 506b′ respectively. In other embodiments, after performing the bonding process, the first gaps 506a and the second gaps 506b are still in slender gap-like shapes but not in hole-like shapes. In addition, after performing the bonding process, the bonding head 511 is removed to form the display device 500.

The similarity between the display device 500 and the display device 300 is that the sectional areas of the first and second bonding materials 505a, 505b are smaller than the contact areas of the first and third conductive pads 503a, 503b that are adjacent to the substrate 501 before performing the bonding process. Moreover, in comparison with the display device 300, the first and second bonding materials 505a, 505b of the display device 500 have more gaps or holes inside, such that there are more accommodation spaces between the first and second conductive pads 503a, 507a, and between the third and fourth conductive pads 503b, 507b. Therefore, successful bonding between the first and second illumination structures 509a, 509b and the substrate 501 can be ensured, and damage to the devices and short circuits can be avoided.

Furthermore, as shown in FIG. 5B on the left, the sectional areas of the first bonding materials 505a of the display device 500 are smaller than the contact areas of the first conductive pads 503a that are adjacent to the substrate 501. Specifically, line A′-A′ is the central line of the first bonding materials 505a in the direction that is parallel to the surface of the substrate 501. The first bonding materials 505a have a thickness “t”, and the sectional areas of the first bonding materials 505a are located in the range from the line A′-A′ plus 15% of the thickness “t” upward or downward.

In other words, the first bonding materials 505a have cross-sections perpendicular to the substrate 501. In the cross-sections, the first bonding materials 305a have concave cross-sectional contours in the range from the line A′-A′ plus 15% of the thickness “t” upward or downward.

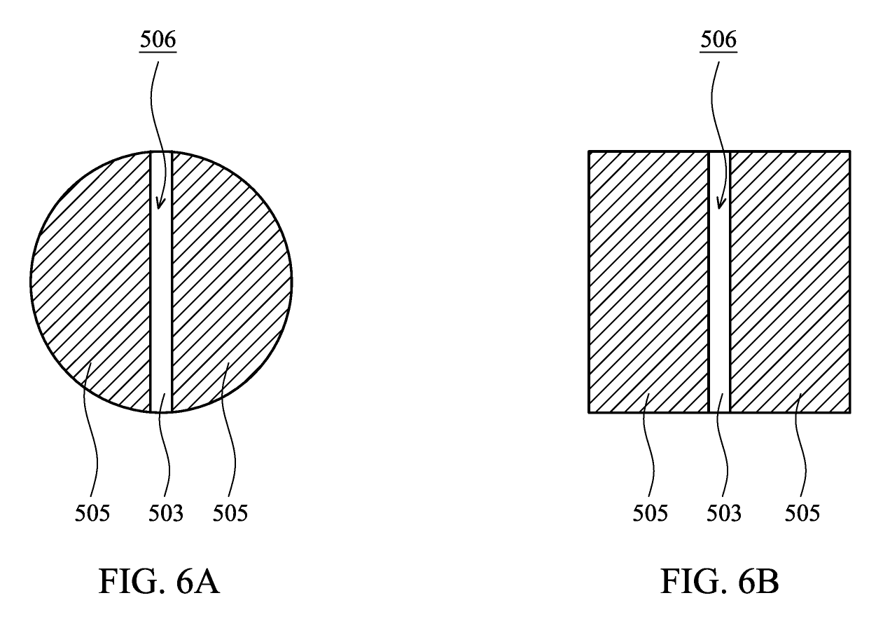

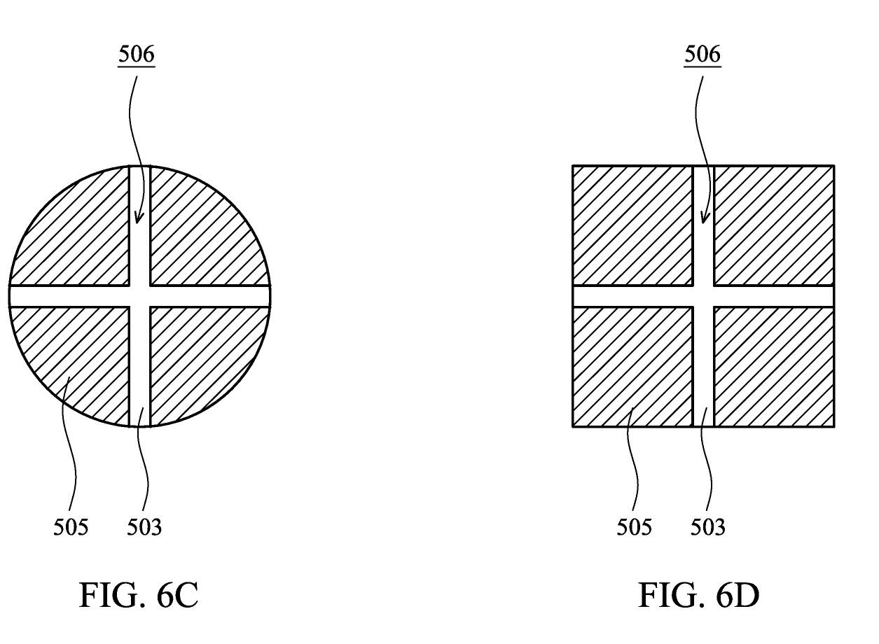

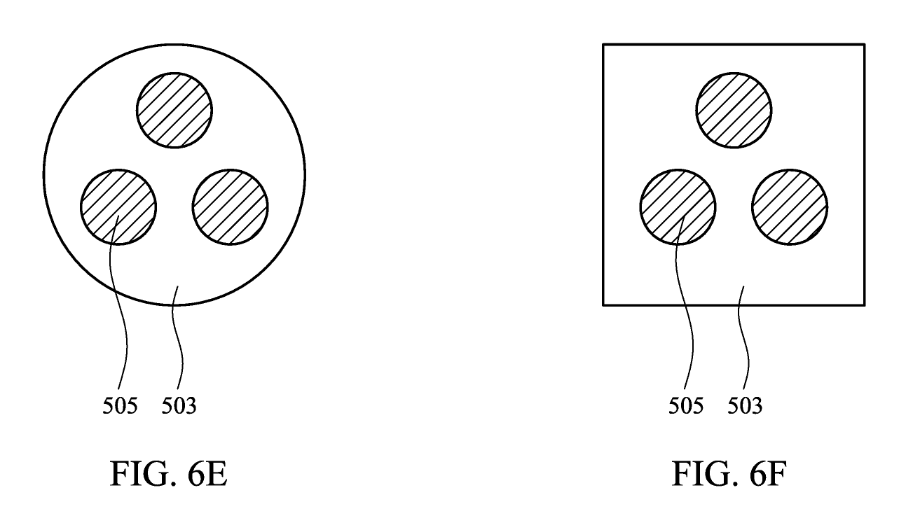

FIGS. 6A to 6F are top views of the display device 500 illustrating the bonding materials on the conductive pads along line A-A of FIG. 5A, line B-B of FIG. 5A, line A′-A′ of FIG. 5B or line B′-B′ of FIG. 5B. It should be noted that the embodiments of the present disclosure are not limited to these examples.

In some embodiments, as shown in FIGS. 6A and 6B, the shape of the conductive pads 503 can be circular or rectangular (the conductive pads 503 may include the first and third conductive pads 503a, 503b), and the bonding materials 505 on the conductive pads 503 may have a substantially circular or rectangular shape (the bonding materials may include the first and second bonding materials 505a, 505b). It is worth noting that since the bonding materials 505 have gaps 506 inside (the gaps 506 may include the first and second gaps 506a, 506b), in the top views along line A-A, line B-B of FIG. 5A, line A′-A′ or line B′-B′ of FIG. 5B, a portion of the conductive pads 503 under the bonding materials 505 is exposed by the gaps 506.

In other embodiments, as shown in FIGS. 6C and 6D, each of the bonding materials 505 has more than one gap 506 inside. The bonding materials 505 shown in FIGS. 6A, 6B, 6C and 6D may be formed by a patterning process that includes a photolithography process and an etch process.

In another embodiment, as shown in FIGS. 6E and 6F, several bonding materials 505 are disposed on a single conductive pad 503, such that the bonding materials 505 on a single conductive pad 503 have accommodation spaces therebetween. In other embodiments, as shown in FIGS. 6E and 6F, several globular bonding materials 505 are disposed on a single conductive pad 503, and the bonding materials 505 may be conductive particles, such as solder balls.

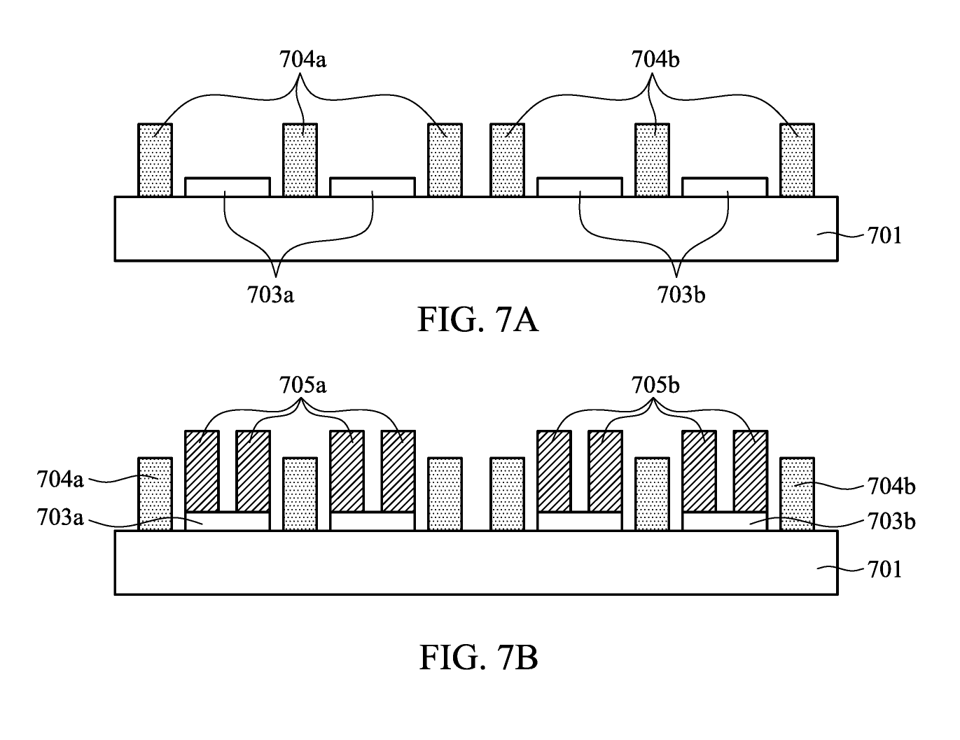

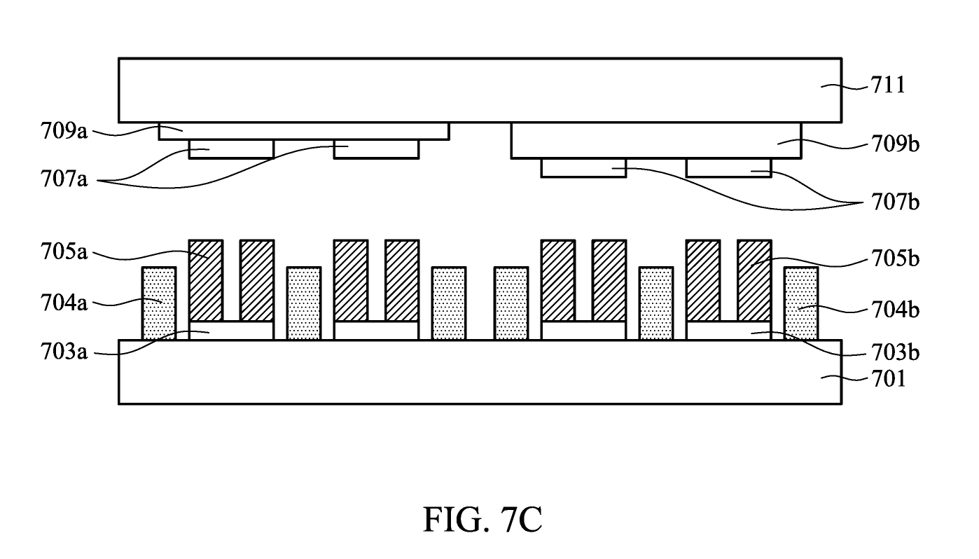

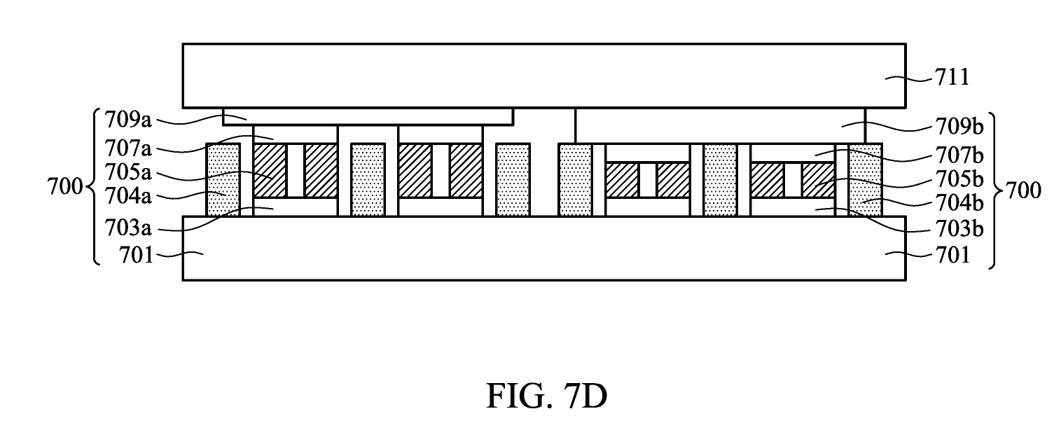

FIGS. 7A to 7D are cross-sectional views illustrating an exemplary sequential formation process of a display device 700 in accordance with some embodiments.

As shown in FIG. 7A, several first conductive pads 703a, third conductive pads 703b, first spacers 704a and second spacers 704b are formed on a substrate 701, in accordance with some embodiments. Specifically, at least one of the first spacers 704a is disposed in the region which is intended to be bonded with the first illumination component subsequently, and at least one of the second spacers 704b is disposed in the region which is intended to be bonded with the second illumination component subsequently. In some embodiments, at least one spacer is disposed in the regions which are intended to be bonded with the first and second illumination components subsequently. Moreover, a spacer may be disposed between the regions which are intended to be bonded with the first and second illumination components subsequently. The materials and processes of the first and third conductive pads 703a and 703b are similar to, or the same as, those used to form the first and third conductive pads 303a, 303b of the display device 300 and are not repeated herein for simplicity. In some embodiments, the first and second spacers 704a, 704b may be formed by photolithography and etching processes, and have the same thickness. In addition, the first and second spacers 704a, 704b may be insulating materials, for example, silicon oxide, silicon oxynitride, silicon nitride, polymer materials that can be used in photolithography and etching or a combination thereof.

Next, as shown in FIG. 7B, patterned first and second bonding materials 705a, 705b are disposed on the first and third conductive pads 403a, 703b respectively. It is worth noting that the first and second bonding materials 705a, 705b are thicker than the first and second spacers 704a, 704b. In addition, the processes and materials of the first and second bonding materials 705a, 705b are similar to, or the same as, those used to form the first and second bonding materials 305a, 305b of the display device 300 and are not repeated herein for simplicity.

Moreover, as shown in FIG. 7C, the first illumination structure 709a and the second illumination structure 709b are adsorbed or adhered by a bonding head 711. The first illumination structure 709a is thinner than the second illumination structure 709b. Several second conductive pads 707a are formed on the bottom surface of the first illumination structure 709a. The first illumination structure 709a and the second conductive pads 707a located on its bottom surface compose a first illumination component. Several fourth conductive pads 707b are formed on the bottom surface of the second illumination structure 709b. The second illumination structure 709b and the fourth conductive pads 707b located on its bottom surface compose a second illumination component. In some embodiments, the first and second illumination structures 709a and 709b may be light-emitting diodes (LED). In addition, the processes and materials of the second and fourth conductive pads 707a and 707b are similar to, or the same as, those used to form the second and fourth conductive pads 307a and 307b of the display device 300 and are not repeated herein for simplicity.

As shown in FIG. 7D, a bonding process is performed by using the bonding head 711 to make the first and second illumination structures 709a and 709b bond to the substrate 701 at the same time, such that the display device 700 is formed under the bonding head 711, in accordance with some embodiments. The temperature and the pressure applied through the bonding head 711 are similar to that of the bonding head 311 in FIG. 3B and are not repeated herein for simplicity. When the thicker second illumination structure 709b is in contact with the second spacers 704b, the bonding process is finished. At this time, the first bonding materials 705a are thicker than the second bonding materials 705b, the thickness of one the first spacers 704a is less than the sum of the thicknesses of one of the first conductive pads 703a, one of the first bonding materials 705a, and one of the second conductive pads 707a. Moreover, the thickness of one of the second spacers 704b is equal to the sum of the thicknesses of one of the third conductive pads 703b, one of the second bonding materials 705b, and one of the fourth conductive pads 707b. In addition, after performing the bonding process, the bonding head 711 is removed to form the display device 700.

Before performing the bonding process, the first and second bonding materials 705a, 705b are thicker than the first and second spacers 704a, 704b. When the thicker second illumination structure 709b is in contact with the second spacer 704b during the bonding process, successful bonding between the first and second illumination structures 709a, 709b and the substrate 701 can be ensured.

Moreover, since the first and second spacers 704a, 704b disposed on the substrate 701 have the same thickness, when the bonding process is finished, the distance between the surface of the substrate 701 close to the first illumination structure 709a and the surface of the first illumination structure 709a far from the substrate 701 is equal to the distance between the surface of the substrate 701 close to the second illumination structure 709b and the surface of the second illumination structure 709b far from the substrate 701. By disposing the first spacers 704a with the same thickness as the second spacers 704b, the entire thickness of the display device 700 can be controlled more precisely.

On the other hand, the first and second spacers 704a, 704b can prevent the bonding materials on different conductive pads being in contact with each other. Therefore, short circuits can be avoided.

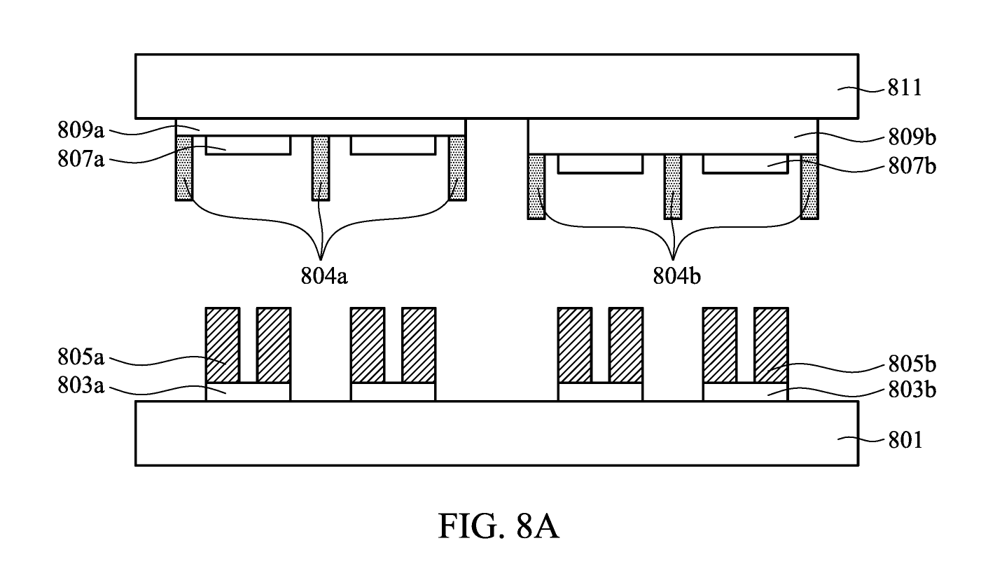

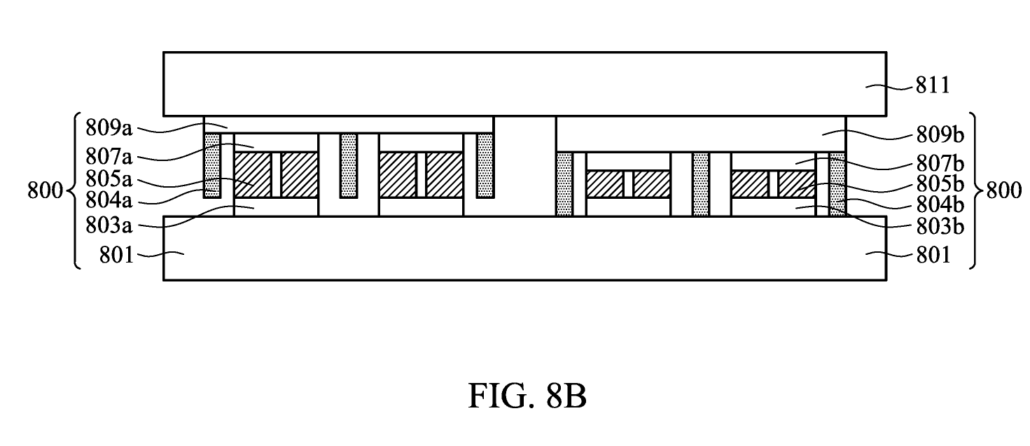

FIGS. 8A and 8B are cross-sectional views illustrating an exemplary sequential formation process of a display device 800 in accordance with some embodiments. The components shown in FIGS. 8A and 8B are similar to those shown in FIGS. 7C and 7D and are not repeated herein for simplicity.

In some embodiments, the difference between FIGS. 8A and 7C is the positions of the first and second spacers 804a, 804b. As shown in FIG. 8A, the first and second spacers 804a, 804b are disposed on the first and second illumination structures 809a, 809b respectively. At least one of the first spacers 804a is disposed on the illumination structure 809a, and at least one of the second spacers 804b is disposed on the illumination structure 809b. Moreover, in FIG. 8A, the first and second bonding materials 805a, 805b are thicker than the first and second spacers 804a, 804b, which is similar to FIG. 7C.

Next, as shown in FIG. 8B, a bonding process is performed by using the bonding head 811 to make the first and second illumination structures 809a and 809b bond to the substrate 801 at the same time, such that the display device 800 is formed under the bonding head 811. When the thicker second illumination structure 809b is in contact with the second spacers 804b, the bonding process is finished. At this time, the first bonding materials 805a are thicker than the second bonding materials 805b, the thickness of one the first spacers 804a is less than the sum of the thicknesses of one of the first conductive pads 803a, one of the first bonding materials 805a, and one of the second conductive pads 807a. Moreover, the thickness of one of the second spacers 804b is equal to the sum of the thicknesses of one of the third conductive pads 803b, one of the second bonding materials 805b, and one of the fourth conductive pads 807b. In addition, after performing the bonding process, the bonding head 811 is removed to form the display device 800.

Similar to the display device 700, the first and second bonding materials 805a, 805b of the display device 800 are thicker than the first and second spacers 804a, 804b before performing the bonding process, and the first and second spacers 804a, 804b of the display device 800 have the same thickness. Therefore, successful bonding between the first and second illumination structures 809a, 809b and the substrate 801 can be ensured, and the entire thickness of the display device 800 can be controlled more precisely.

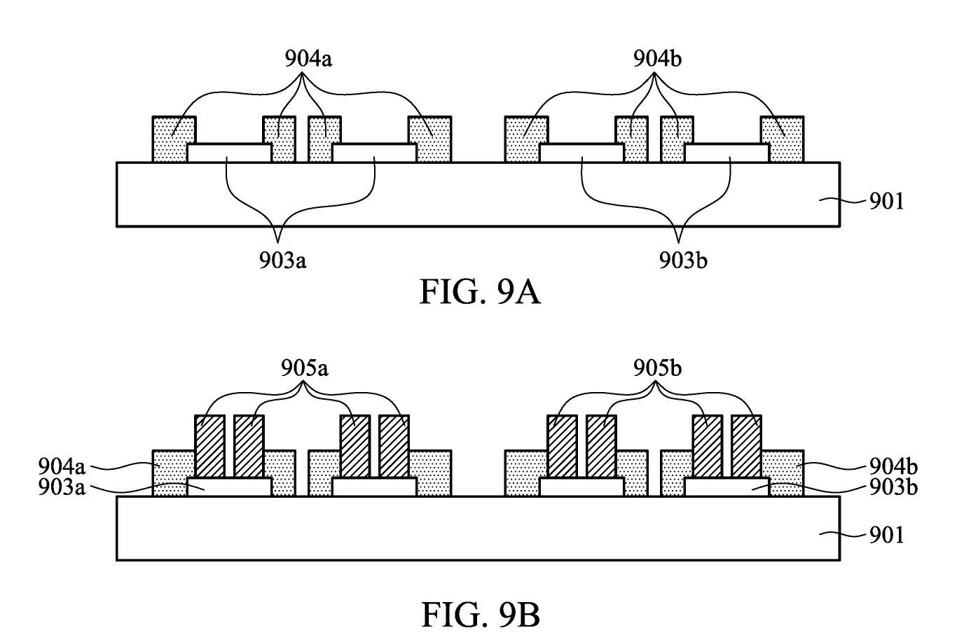

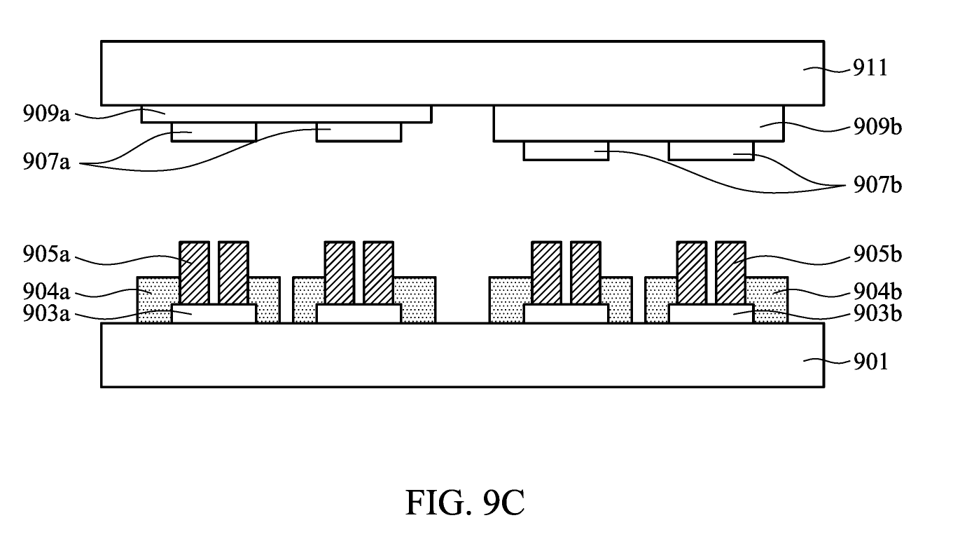

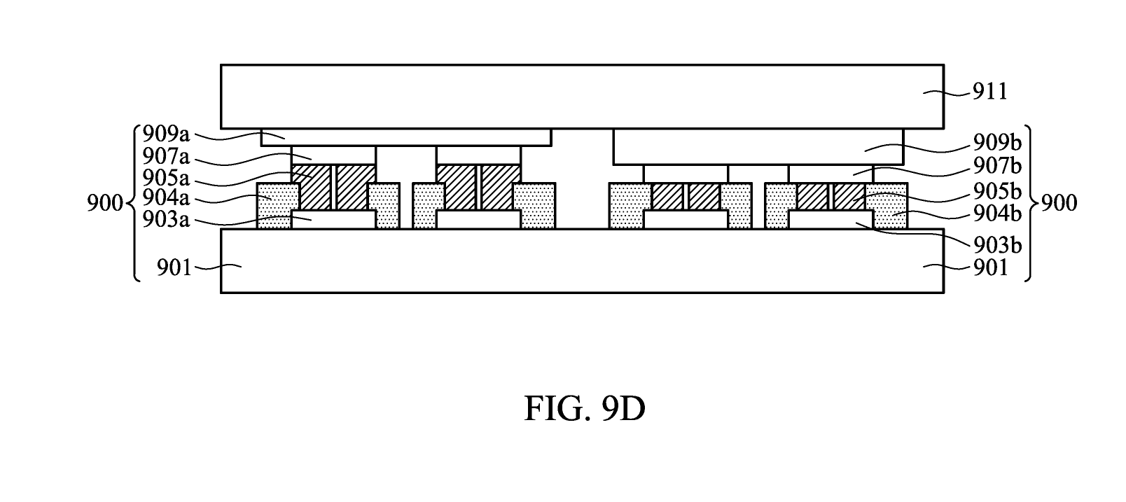

FIGS. 9A to 9D are cross-sectional views illustrating an exemplary sequential formation process of a display device 900 in accordance with some embodiments.

As shown in FIG. 9A, several first conductive pads 903a, third conductive pads 903b, first spacers 904a and second spacers 904b are formed on a substrate 901, in accordance with some embodiments. Specifically, the first spacers 904a are disposed on both sides of each first conductive pad 903a, and the second spacers 904b are disposed on both sides of each second conductive pad 903b. The materials and processes of the first and third conductive pads 903a and 903b are similar to, or the same as, those used to form the first and third conductive pads 303a, 303b of the display device 300, the materials and processes of the first and second spacers 904a and 904b are similar to, or the same as, those used to form the first and second spacers 304a and 304b of the display device 300. Therefore, the aforementioned materials and processes are not repeated herein for simplicity.

The difference between FIGS. 9A and 7A is the positions of the first and second spacers 904a, 904b. As shown in FIG. 9A, the first and second spacers 904a, 904b are in contact with the first and third conductive pads 903a, 903b respectively, and a portion of the first and second spacers 904a, 904b can respectively cover a portion of the first and third conductive pads 903a, 903b. In other embodiments, since the distances between each two first conductive pads 903a are too small, a single first spacer 904a may be disposed between each two adjacent first conductive pads 903a. Similarly, a single second spacer 904b may be disposed between each two adjacent third conductive pads 903b.

Next, as shown in FIG. 9B, patterned first and second bonding materials 905a, 905b are disposed on the first and third conductive pads 903a, 903b respectively. It is worth noting that the first and second bonding materials 905a, 905b are thicker than the first and second spacers 904a, 904b. In some embodiments, the patterned first bonding materials 905a may be in contact with the first spacers 904a, and the patterned second bonding materials 905b may be in contact with the second spacers 904b. In other embodiments, the patterned first bonding materials 905a may be not in contact with the first spacers 904a, and the patterned second bonding materials 905b may be not in contact with the second spacers 904b.

Moreover, as shown in FIG. 9c, the first illumination structure 909a and the second illumination structure 909b are adsorbed or adhered by a bonding head 911. The first illumination structure 909a is thinner than the second illumination structure 909b. Several second conductive pads 907a are formed on the bottom surface of the first illumination structure 909a, and several fourth conductive pads 907b are formed on the bottom surface of the second illumination structure 909b. The processes and materials of the first and second illumination structures 909a, 909b are similar to, or the same as, those used to form the first and second illumination structures 309a, 309b of the display device 300, the processes and materials of the second and fourth conductive pads 907a, 907b are similar to, or the same as, those used to form the second and fourth conductive pads 307a, 307b of the display device 300. Therefore, the aforementioned processes and materials are not repeated herein for simplicity.

As shown in FIG. 9D, a bonding process is performed by using the bonding head 911 to make the first and second illumination structures 909a and 909b bond to the substrate 901 at the same time, such that the display device 900 is formed under the bonding head 911, in accordance with some embodiments. The temperature and the pressure applied through the bonding head 911 are similar to that of the bonding head 311 in FIG. 3B and are not repeated herein for simplicity. When the thicker second illumination structure 909b is in contact with the second spacers 904b, the bonding process is finished. At this time, the first bonding materials 905a are thicker than the second bonding materials 905b, the thickness of one the first spacers 904a is less than the sum of the thicknesses of one of the first conductive pads 903a, one of the first bonding materials 905a, and one of the second conductive pads 907a. Moreover, the thickness of one of the second spacers 904b is equal to the sum of the thicknesses of one of the third conductive pads 903b, one of the second bonding materials 905b, and one of the fourth conductive pads 907b. In some embodiments, after performing the bonding process, the portion of the first spacers 904a covering the first conductive pads 903a is thinner than the first bonding materials 905a. In addition, after performing the bonding process, the bonding head 911 is removed to form the display device 900.

Successful bonding between the first and second illumination structures 909a, 909b and the substrate 901 can be ensured by the disposition of the first and second spacers 904a, 904b, and the entire thickness of the display device 900 can be controlled more precisely. In addition, since both of the first and second spacers 904a, 904b have a portion located respectively on the first conductive pads 903a and the third conductive pads 903b, the inner spaces can be occupied in advance by the first and second bonding materials 905a, 905b during the bonding process, so that the outward extrusion of the first and second bonding materials 905a, 905b may be further prevented, and short circuits may also be avoided.

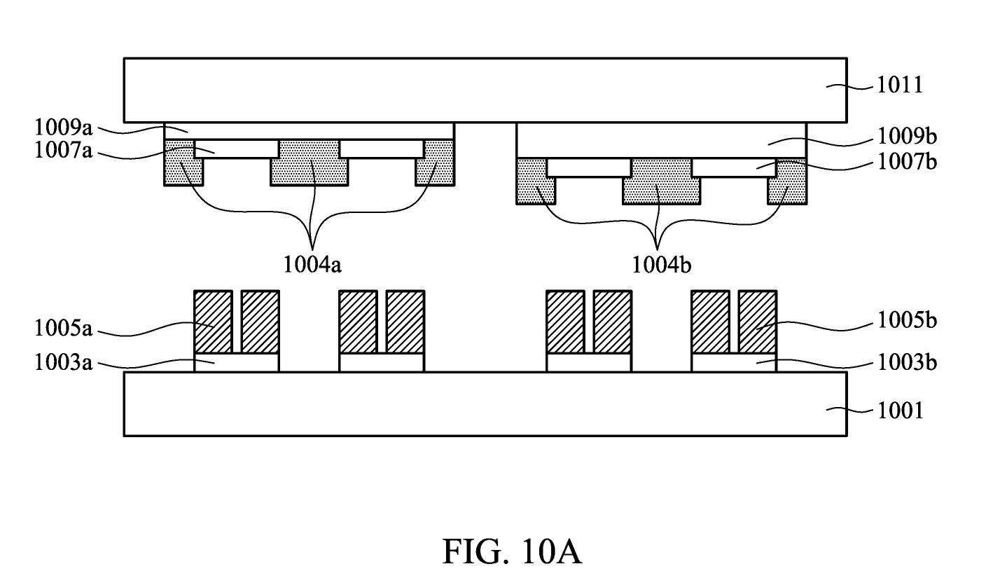

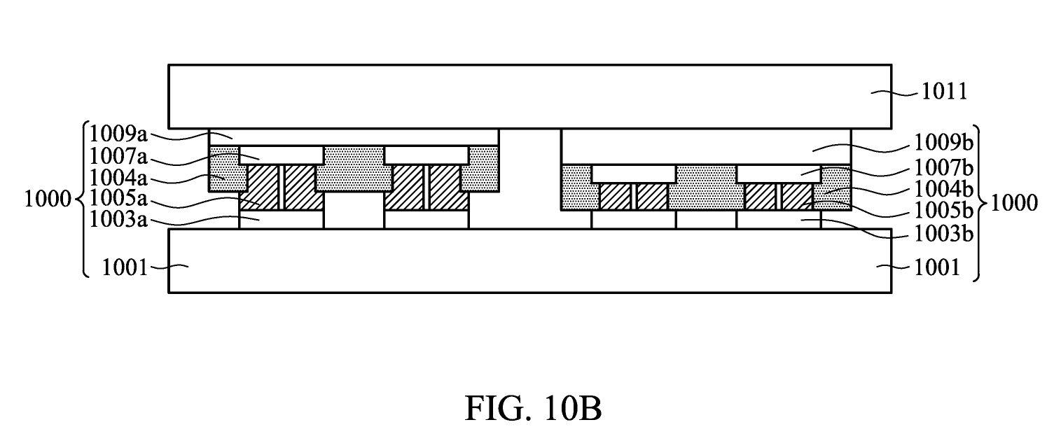

FIGS. 10A and 10B are cross-sectional views illustrating an exemplary sequential formation process of a display device 1000 in accordance with some embodiments. The components shown in FIGS. 10A and 10B are similar to those shown in FIGS. 9C and 9D and are not repeated herein for simplicity.

In some embodiments, the difference between FIGS. 10A and 9C is the positions of the first and second spacers 1004a, 1004b. As shown in FIG. 10A, the first and second spacers 1004a, 1004b are disposed on the first and second illumination structures 1009a, 1009b respectively. Furthermore, only a single first spacer 1004a is disposed between each two adjacent third conductive pads 1007a, both sides of the first spacer 1004a have a portion covering the adjacent third conductive pads 1007a. Only a single second spacer 1004b is disposed between each two adjacent fourth conductive pads 1007b, both sides of the second spacer 1004b have a portion covering the adjacent fourth conductive pads 1007b.

In other embodiments, more than one of the first spaces 1004a can be disposed between two adjacent third conductive pads 1007a, and more than one of the second spaces 1004b can be disposed between two adjacent fourth conductive pads 1007b. Moreover, similar to FIG. 9C, the first and second bonding materials 1005a, 1005b of FIG. 10A are thicker than the first and second spacers 1004a, 1004b.

Next, as shown in FIG. 10B, a bonding process is performed by using the bonding head 1011 to make the first and second illumination structures 1009a and 1009b bond to the substrate 1001 at the same time, such that the display device 1000 is formed under the bonding head 1011. When the second spacers 1004b on the thicker second illumination structure 1009b are in contact with the substrate 1001, the bonding process is finished. At this time, the first bonding materials 1005a are thicker than the second bonding materials 1005b, the thickness of one the first spacers 1004a is less than the sum of the thicknesses of one of the first conductive pads 1003a, one of the first bonding materials 1005a, and one of the second conductive pads 1007a. Moreover, the thickness of one of the second spacers 1004b is equal to the sum of the thicknesses of one of the third conductive pads 1003b, one of the second bonding materials 1005b, and one of the fourth conductive pads 1007b. In some embodiments, after performing the bonding process, the portion of the first spacers 1004a covering the first conductive pads 1003a is thinner than the first bonding materials 1005a. In addition, after performing the bonding process, the bonding head 1011 is removed to form the display device 1000.

Similar to the display device 900, by disposing the first and second spacers 1004a, 1004b in the display device 1000, successful bonding between the first and second illumination structures 1009a, 1009b and the substrate 1001 can be ensured, and the entire thickness of the display device 1000 can be controlled more precisely. In addition, since both of the first and second spacers 1004a, 1004b have a portion located respectively on the second conductive pads 1007a and the fourth conductive pads 1007b, the inner spaces can be occupied in advance by the first and second bonding materials 1005a, 1005b during the bonding process, so that the outward extrusion of the first and second bonding materials 1005a, 1005b may be further prevented, and short circuits may also be avoided.

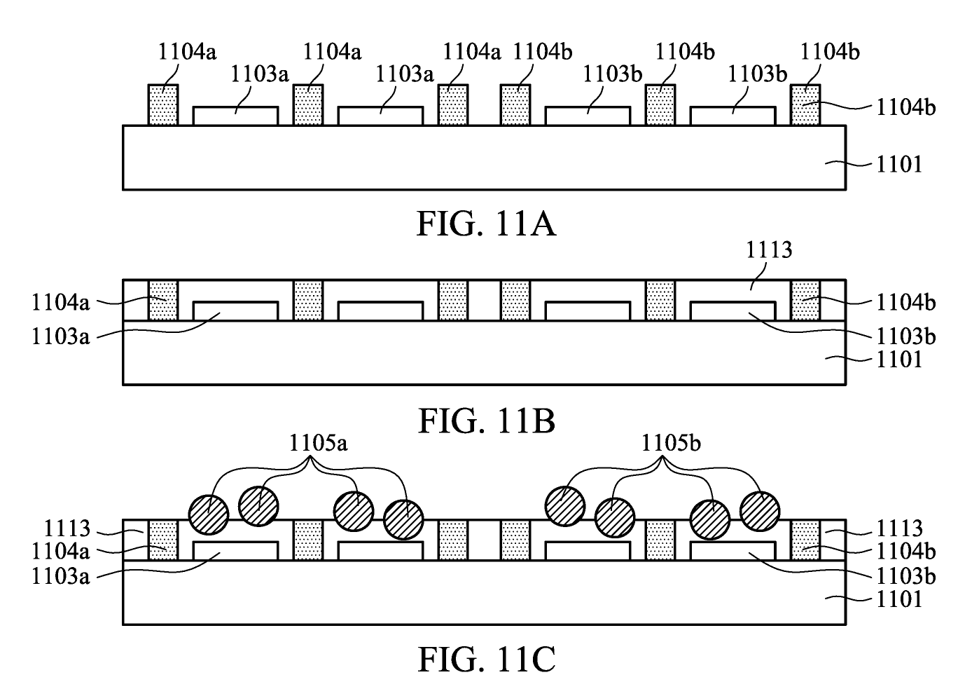

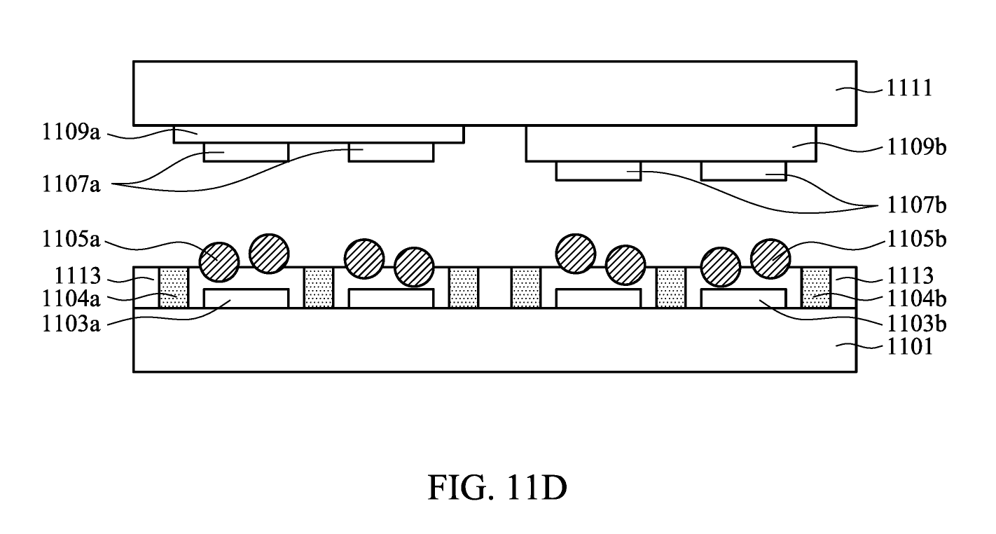

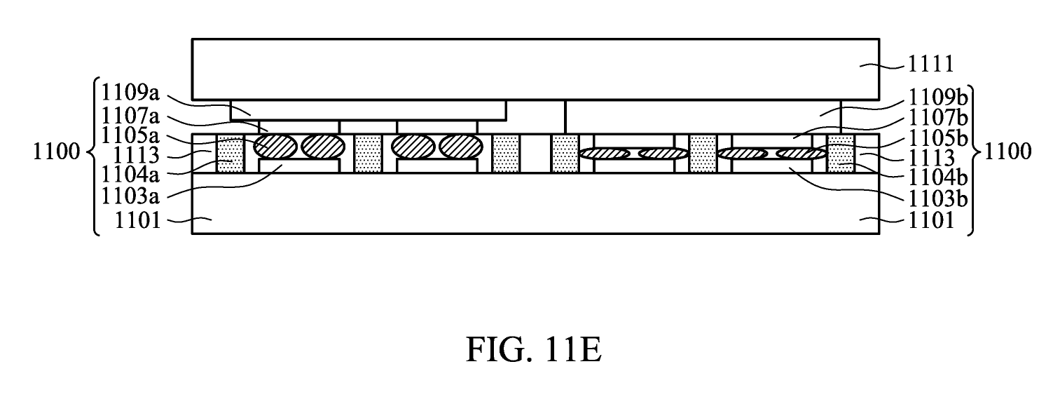

FIGS. 11A to 11E are cross-sectional views illustrating an exemplary sequential formation process of a display device 1100 in accordance with some embodiments.

As shown in FIG. 11A, several first conductive pads 1103a, third conductive pads 1103b, first spacers 1104a and second spacers 1104b are formed on a substrate 1101, in accordance with some embodiments. The materials and processes of the first and third conductive pads 1103a and 1103b are similar to, or the same as, those used to form the first and third conductive pads 303a, 303b of the display device 300, the materials and processes of the first and second spacers 1104a and 1104b are similar to, or the same as, those used to form the first and second spacers 304a and 304b of the display device 300. Therefore, the aforementioned materials and processes are not repeated herein for simplicity.

Next, as shown in FIG. 11B, a glue coating 1113 is formed on the substrate 1101, the first conductive pads 1103a and the third conductive pads 1103b. In some embodiments, the glue coating 1113 is not a solid insulating material, and the reflection rate of the glue coating 1113 is between the reflection rates of the air and the illumination structures, for example, in a range from about 1 to about 2.4. In some embodiments, the reflection rate of the glue coating 1113 is in a range from about 1.4 to about 1.6. The glue coating 1113 has functions of light-capturing and protection. In other embodiments, the glue coating 1113 can cover the first and second spacers 1104a, 1104b in further.

Moreover, as shown in FIG. 11C, several first and second bonding materials 1105a, 1105b are disposed on the glue coating 1113, and a portion of the first and second bonding material 1105a, 1105b is embedded into the glue coating 1113. It is worth noting that the first and second bonding materials 1105a, 1105b are thicker than the first and second spacers 1104a, 1104b. In some embodiments, the first and second bonding materials 1105a, 1105b may be globular conductive particles, such as solder balls or Ni—Au plating metal balls. In addition, the first and second bonding materials 1105a, 1105b are formed by injecting or stamping, and disposed on the glue coating 1113 above the corresponding first and third conductive pads 1103a, 1103b.

As shown in FIG. 11D, the first illumination structure 1109a and the second illumination structure 1109b are adsorbed or adhered by a bonding head 1111. The first illumination structure 1109a is thinner than the second illumination structure 1109b. Several second conductive pads 1107a are formed on the bottom surface of the first illumination structure 1109a, and several fourth conductive pads 1109b are formed on the bottom surface of the second illumination structure 1109b. The processes and materials of the first and second illumination structures 1109a, 1109b are similar to, or the same as, those used to form the first and second illumination structures 309a, 309b of the display device 300, the processes and materials of the second and fourth conductive pads 1107a, 1107b are similar to, or the same as, those used to form the second and fourth conductive pads 307a, 307b of the display device 300. Therefore, the aforementioned processes and materials are not repeated herein for simplicity.

As shown in FIG. 11E, a bonding process is performed by using the bonding head 1111 to make the first and second illumination structures 1109a, 1109b bond to the substrate 1101 at the same time, such that the display device 1100 is formed under the bonding head 1111, in accordance with some embodiments. The temperature and the pressure applied through the bonding head 1111 are similar to that of the bonding head 311 in FIG. 3B and are not repeated herein for simplicity. When the thicker second illumination structure 1109b is in contact with the second spacers 1104b, the bonding process is finished. At this time, the first bonding materials 1105a are thicker than the second bonding materials 1105b, the thickness of one the first spacers 1104a is less than the sum of the thicknesses of one of the first conductive pads 1103a, one of the first bonding materials 1105a, and one of the second conductive pads 1107a. Moreover, the thickness of one of the second spacers 1104b is equal to the sum of the thicknesses of one of the third conductive pads 1103b, one of the second bonding materials 1105b, and one of the fourth conductive pads 1107b. In addition, after performing the bonding process, the bonding head 1111 is removed to form the display device 1100.

In comparison with the display devices 700, 800, 900 and 1000, the first and second bonding materials 1105a, 1105b of the display device 1100 can be easily disposed by the disposition of the glue coating 1113. Thus, the numbers of the entire forming steps can be decreased.

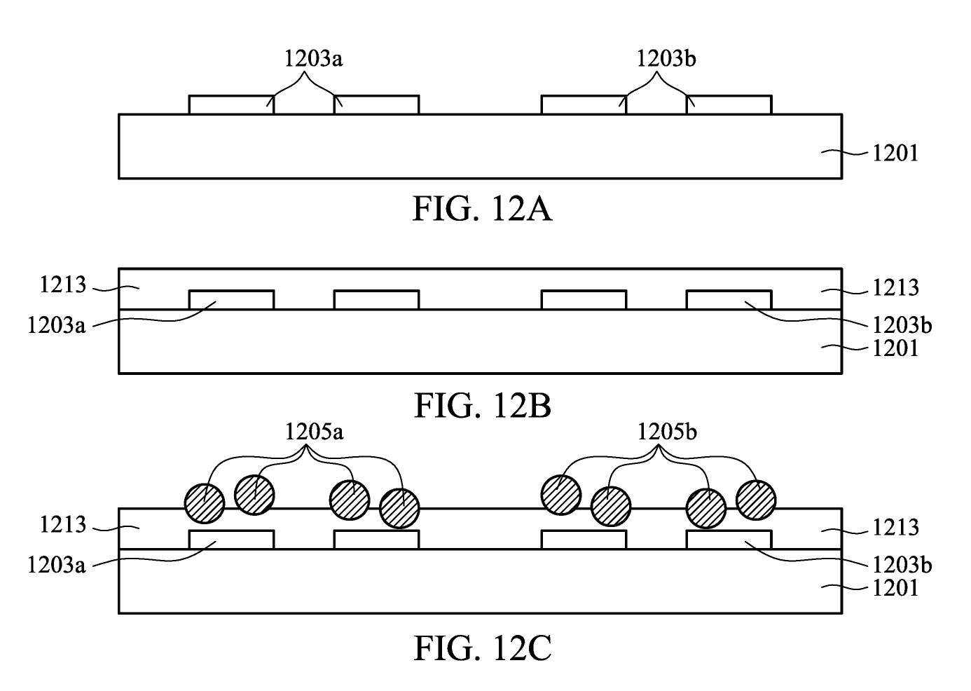

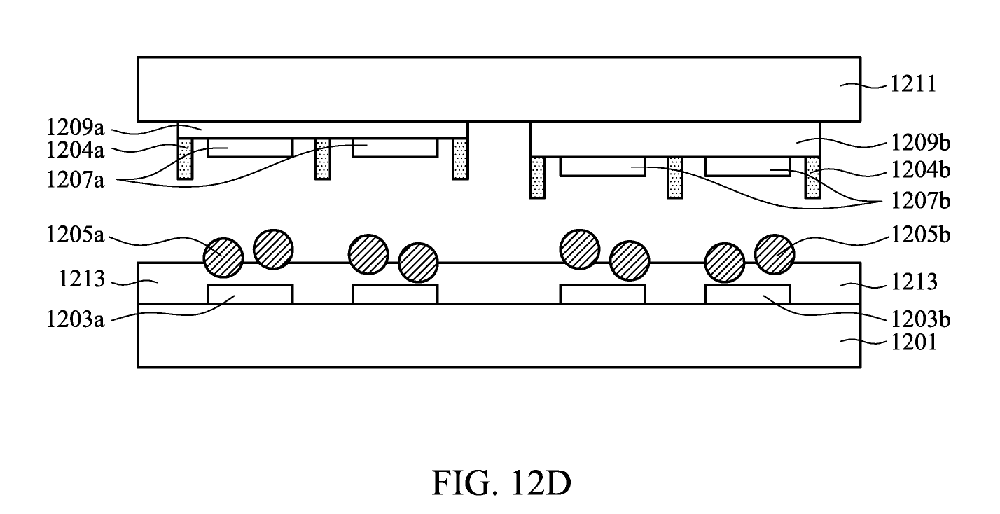

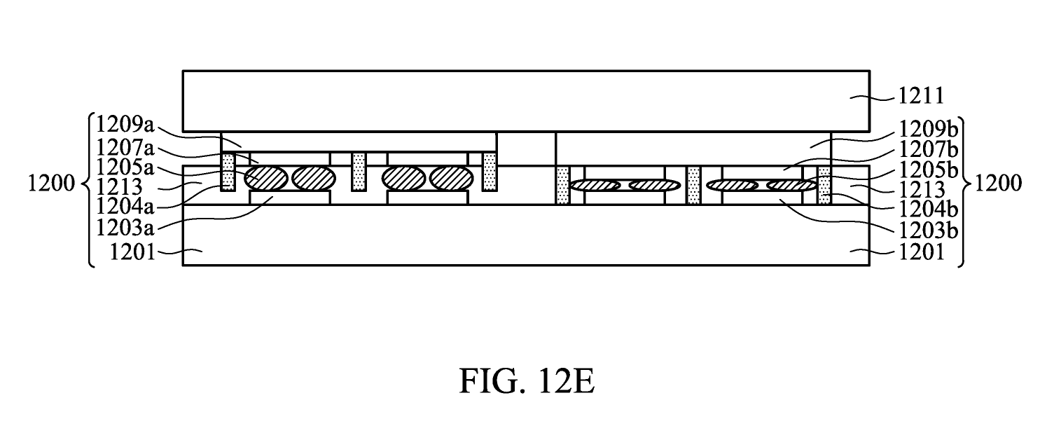

FIGS. 12A to 12E are cross-sectional views illustrating an exemplary sequential formation process of a display device 1200 in accordance with some embodiments. The components shown in FIGS. 12A to 12E are similar to those shown in FIGS. 11A to 11E and are not repeated herein for simplicity.

In some embodiments, as shown in FIG. 12A, several first conductive pads 1203a and third conductive pads 1203b are disposed on a substrate 1201. The materials and processes of the first and third conductive pads 1203a, 1203b are similar to, or the same as, those used to form the first and third conductive pads 303a, 303b of the display device 300 and are not repeated herein for simplicity.

Next, as shown in FIG. 12B which is similar to FIG. 11B, a glue coating 1213 is formed on the first and third conductive pads 1203a, 1203b. In some embodiments, the processes and materials of the glue coating 1213 are similar to, or the same as, those used to form the glue coating 1113 in FIG. 11B and are not repeated herein for simplicity.

Moreover, as shown in FIG. 12C which is similar to FIG. 11C, several first and second bonding materials 1205a, 1205b are disposed on the glue coating 1213, and a portion of the first and second bonding materials 1205a, 1205b is embedded into the glue coating 1213. In some embodiments, the processes and materials of the first and second bonding materials 1205a, 1205b are similar to, or the same as, those used to form the first and second bonding materials 1105a, 1105b in FIG. 11C and are not repeated herein for simplicity.

As shown in FIG. 12D which is similar to FIG. 11D, the first illumination structure 1209a and the second illumination structure 1209b are adsorbed or adhered by a bonding head 1211. The first illumination structure 1209a is thinner than the second illumination structure 1209b. Several second conductive pads 1207a are formed on the bottom surface of the first illumination structure 1209a, and several fourth conductive pads 1209b are formed on the bottom surface of the second illumination structure 1209b. The processes and materials of the first and second illumination structures 1209a, 1209b are similar to, or the same as, those used to form the first and second illumination structures 309a, 309b of the display device 300, the processes and materials of the second and fourth conductive pads 1207a, 1207b are similar to, or the same as, those used to form the second and fourth conductive pads 307a, 307b of the display device 300. Therefore, the aforementioned processes and materials are not repeated herein for simplicity.

The difference between FIGS. 12D and 11D is the positions of the first and second spacers 1204a, 1204b. As shown in FIG. 12D, the first and second spacers 1204a, 1204b are disposed on the first and second illumination structures 1209a, 1209b respectively. It is worth noting that the first and second spacers 1204a, 1204b are thinner than the first and second bonding materials 1205a, 1205b.

Next, as shown in FIG. 12E, a bonding process is performed by using the bonding head 1211 to make the first and second illumination structures 1209a, 1209b bond to the substrate 1201 at the same time, such that the display device 1200 is formed under the bonding head 1211. The temperature and the pressure applied through the bonding head 1211 are similar to that of the bonding head 311 in FIG. 3B and are not repeated herein for simplicity. When the second spacers 1204b on the thicker second illumination structure 1209b are in contact with the substrate 1201, the bonding process is finished. At this time, the first bonding materials 1205a are thicker than the second bonding materials 1205b, the thickness of one the first spacers 1204a is less than the sum of the thicknesses of one of the first conductive pads 1203a, one of the first bonding materials 1205a, and one of the second conductive pads 1207a. Moreover, the thickness of one of the second spacers 1204b is equal to the sum of the thicknesses of one of the third conductive pads 1203b, one of the second bonding materials 1205b, and one of the fourth conductive pads 1207b. In addition, after performing the bonding process, the bonding head 1211 is removed to form the display device 1200.

Similar to the display device 1100, the first and second bonding materials 1205a, 1205b of the display device 1200 can be easily disposed by the disposition of the glue coating 1213, and the numbers of the entire forming steps can be decreased.

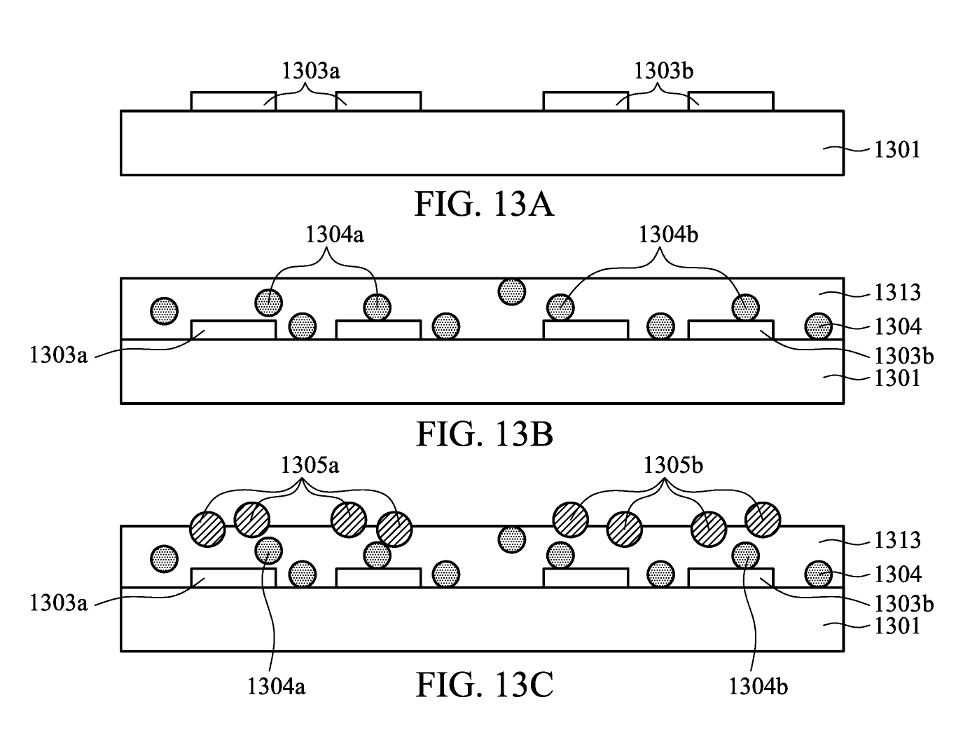

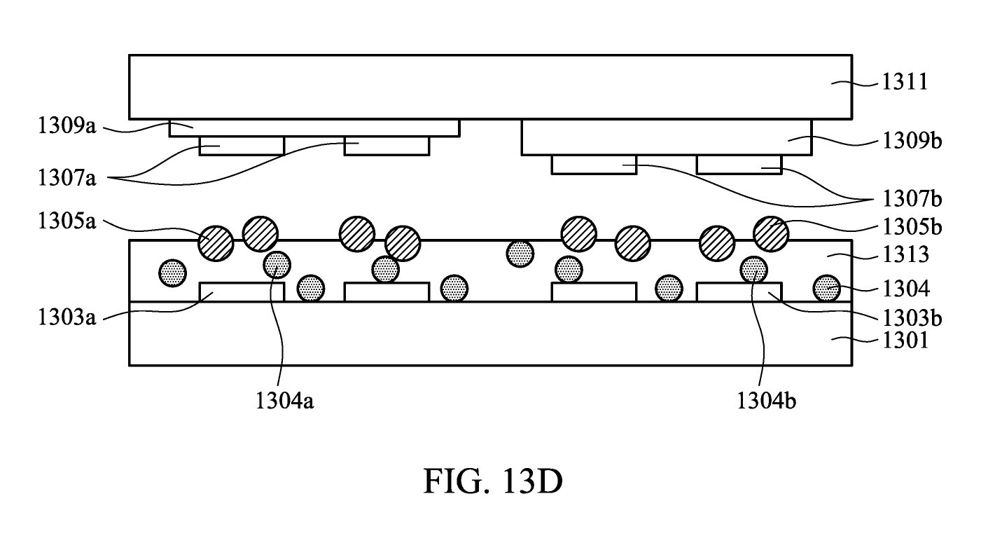

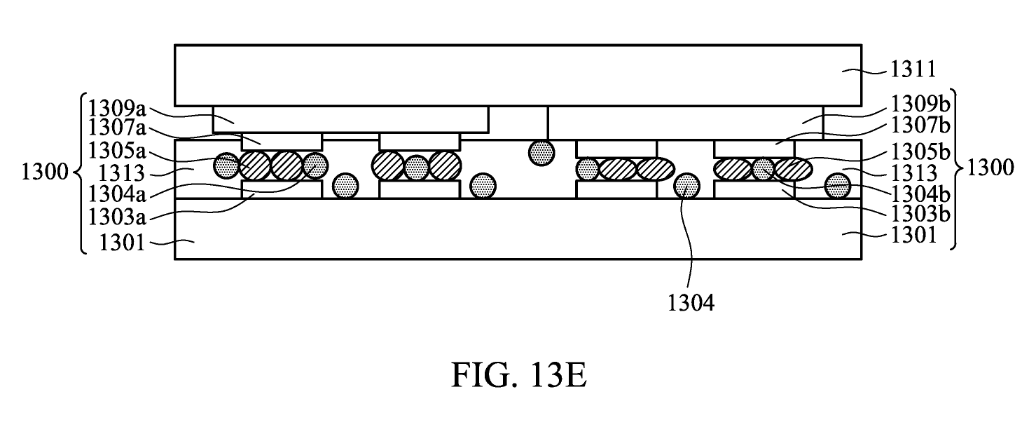

FIGS. 13A to 13E are cross-sectional views illustrating an exemplary sequential formation process of a display device 1300 in accordance with some embodiments.

As shown in FIG. 13A, several first conductive pads 1303a, third conductive pads 1303b are formed on a substrate 1301, in accordance with some embodiments. The materials and processes of the first and third conductive pads 1303a, 1303b are similar to, or the same as, those used to form the first and third conductive pads 303a, 303b of the display device 300 and are not repeated herein for simplicity.

Next, as shown in FIG. 13B, a glue coating 1313 including spacers 1304 is formed on the substrate 1301, the first conductive pads 1303a and the third conductive pads 1303b. The materials and processes of the glue coating 1313 and spacers 1304 are similar to, or the same as, those used to form the glue coating 1113, the first and second spacers 1104a, 1104b of FIG. 11B and are not repeated herein for simplicity. In some embodiments, after forming the glue coating 1313 including the spacers 1304, the spacers 1304 on the first conductive pads 1303a are the first spacers 1304a, and the spacers 1304 on the second conductive pads 1303b are the second spacers 1304b. In addition, the quantity of the spacers 1304 in the glue coating 1313 and the viscosity of the glue coating 1313 can be adjusted according to the process requirements.

Moreover, as shown in FIG. 13C, several bonding materials 1305a and 1305b are disposed on the glue coating 1313, and a portion of the first and second bonding materials 1305a, 1305b is embedded into the glue coating 1313. It is worth noting that the first and second bonding materials 1305a, 1305b are thicker than the spacers 1304. In some embodiments, the processes and materials of the first and second bonding materials 1305a, 1305b are similar to, or the same as, those used to form the first and second bonding materials 1105a, 1105b in FIG. 11C and are not repeated herein for simplicity.

As shown in FIG. 13D, the first illumination structure 1309a and the second illumination structure 1309b are adsorbed or adhered by a bonding head 1311. The first illumination structure 1309a is thinner than the second illumination structure 1309b. Several second conductive pads 1307a are formed on the bottom surface of the first illumination structure 1309a, and several fourth conductive pads 1309b are formed on the bottom surface of the second illumination structure 1309b. The processes and materials of the first and second illumination structures 1309a, 1309b are similar to, or the same as, those used to form the first and second illumination structures 309a, 309b of the display device 300, the processes and materials of the second and fourth conductive pads 1307a, 1307b are similar to, or the same as, those used to form the second and fourth conductive pads 307a, 307b of the display device 300. Therefore, the aforementioned processes and materials are not repeated herein for simplicity.

As shown in FIG. 13E, in accordance with some embodiments, a bonding process is performed by using the bonding head 1311 to make the first and second illumination structures 1309a, 1309b bond to the substrate 1301 at the same time, such that the display device 1300 is formed under the bonding head 1311. The temperature and the pressure applied through the bonding head 1311 are similar to that of the bonding head 311 in FIG. 3B and are not repeated herein for simplicity. When the fourth conductive pads 1307b on the thicker second illumination structure 1309b are in contact with the second spacers 1304b on the second conductive pads 1303b, the bonding process is finished. At this time, the first bonding materials 1305a are thicker than the second bonding materials 1305b, the first spacers 1304a are thinner than the first bonding materials 1305a, and the thicknesses of the second spacers 1304b are equal to that of the second bonding materials 1305b. In addition, after performing the bonding process, the bonding head 1311 is removed to form the display device 1300.

Similar to the display devices 1100 and 1200, the first spacers 1304a, the second spacers 1304b, the first bonding materials 1305a and the second bonding materials 1305b of the display device 1300 can be easily disposed by the disposition of the glue coating 1313, and the numbers of the entire forming steps can be decreased.

During the process of eutectic bonding, the illumination structures may not be successfully bonded to the substrate because of the differences in thickness between the illumination structures or the conductive pads. To solve this problem, some embodiments of the disclosure include providing accommodation spaces between the conductive pads on the substrate and the conductive pads on the illumination structures by minimizing sectional areas of the bonding materials or patterning the bonding materials, such that the extra bonding materials produced by extrusion enter into the accommodation spaces, and short circuits between the conductive pads can be avoided.

In addition, in order to ensure a uniform distance between the substrate and each of the surfaces of the illumination structures which is far from the substrate when the bonding process is done, some embodiments of the disclosure include disposing several of the same height spacers between the substrate and the illumination structures. Moreover, by disposing spacers between two adjacent conductive pads on the substrate or on the illumination structures, the problems of short circuits between two adjacent conductive pads on the substrate or on the illumination structures can be avoided after performing the bonding process.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A display device, comprising:
a first conductive pad disposed on a substrate, wherein the first conductive pad has a contact area that is adjacent to the substrate;
a first bonding material disposed on the first conductive pad, wherein the first bonding material has a sectional area that is parallel to a surface of the substrate;
a second conductive pad disposed on the first bonding material; and
a first illumination structure disposed on the second conductive pad,
wherein the sectional area of the first bonding material is smaller than the contact area of the first conductive pad.

2. The display device as claimed in claim 1, wherein the sectional area is located in a range from the center of the first bonding material plus 15% of a thickness of the first bonding material upward or downward.

3. The display device as claimed in claim 1, wherein the first bonding material has a concave cross-sectional contour.

4. The display device as claimed in claim 1, wherein the first bonding material has a gap or a hole therein.

5. The display device as claimed in claim 1, further comprising:
a third conductive pad disposed on the substrate;
a second bonding material disposed on the third conductive pad, wherein the second bonding material has a convex cross-sectional contour;
a fourth conductive pad disposed on the second bonding material; and
a second illumination structure disposed on the fourth conductive pad.

6. The display device as claimed in claim 5, wherein the first bonding material has a thickness that is greater than the thickness of the second bonding material.

7. The display device as claimed in claim 5, wherein the first illumination structure has a thickness that is less than the thickness of the second illumination structure.

8. The display device as claimed in claim 5, wherein the second bonding material has a gap or a hole therein.

9. A display device, comprising:
a first conductive pad disposed on a substrate;
a first bonding material disposed on the first conductive pad;
a second conductive pad disposed on the first bonding material;
a first illumination structure disposed on the second conductive pad; and
a first spacer disposed between the substrate and the first illumination structure.

10. The display device as claimed in claim 9, wherein the first spacer is in contact with the substrate or the first illumination structure, and the first spacer has a thickness that is less than the sum of the thicknesses of the first conductive pad, the first bonding material and the second conductive pad.

11. The display device as claimed in claim 9, wherein a portion of the first spacer extends between the first conductive pad and the second conductive pad, the portion of the first spacer is in contact with the first conductive pad or the second conductive pad, and the portion of the first spacer has a thickness that is less than the thickness of the first bonding material.

12. The display device as claimed in claim 9, further comprising:
a third conductive pad disposed on the substrate;
a second bonding material disposed on the third conductive pad, wherein the first bonding material has a thickness that is greater than the thickness of the second bonding material;
a fourth conductive pad disposed on the second bonding material;
a second illumination structure disposed on the fourth conductive pad; and
a second spacer disposed between the substrate and the second illumination structure.

13. The display device as claimed in claim 12, wherein two sides of the second spacer are respectively in contact with the substrate and the second illumination structure, and the second spacer has a thickness that is equal to the sum of the thicknesses of the third conductive pad, the second bonding material and the fourth conductive pad.

14. The display device as claimed in claim 12, wherein a portion of the second spacer extends between the third conductive pad and the fourth conductive pad, the second spacer is in contact with the substrate or the second illumination structure, and two sides of the portion of the second spacer are respectively in contact with the third conductive pad and the fourth conductive pad.

15. The display device as claimed in claim 9, further comprising:
a glue coating disposed between the substrate and the first illumination structure, wherein the first bonding material is disposed in the glue coating, and the first bonding material is globular in shape.

16. The display device as claimed in claim 15, wherein the first spacer is globular and disposed in the glue coating, and the first spacer is in contact with the first conductive pad and the second conductive pad.

17. A method for forming a display device, comprising:
forming a first conductive pad on a substrate, wherein the first conductive pad has a contact area that is adjacent to the substrate;
forming a second conductive pad on a first illumination structure;
forming a first bonding material on the first conductive pad, wherein the first bonding material has a sectional area that is parallel to a surface of the substrate, the sectional area of the first bonding material is smaller than the contact area of the first conductive pad; and
performing a bonding process to bond the first illumination structure to the substrate.

18. The method as claimed in claim 17, further comprising:
before performing the bonding process, forming a first spacer on the substrate or the first illumination structure, wherein the first bonding material has a thickness that is greater than the thickness of the first spacer, and wherein after performing the bonding process, a side of the first spacer is in contact with the substrate, and the other side of the first spacer is in contact with the first illumination structure.

19. A method for forming a display device, comprising:
forming a first conductive pad on a substrate;
forming a second conductive pad on an illumination structure;
forming a spacer on the substrate or the illumination structure;
forming a glue coating on the substrate and the first conductive pad;
forming a bonding material on the glue coating, and the bonding material is embedded in the glue coating, wherein the bonding material has a thickness that is greater than the thickness of the spacer; and
performing a bonding process to bond the illumination structure to the substrate.

20. A method for forming a display device, comprising:
forming a first conductive pad on a substrate;
forming a second conductive pad on an illumination structure;
forming a glue coating on the substrate and the first conductive pad, or forming the glue coating on the illumination structure and the second conductive pad, wherein the glue coating has a spacer therein;
forming a bonding material on the glue coating, and the bonding material is embedded in the glue coating, wherein the bonding material has a thickness that is greater than the thickness of the spacer; and
performing a bonding process to bond the illumination structure to the substrate.
